(19) United States
(12) Patent Application Publication
(10) Pub. No.: US 2016/0181435 A1
(43) Pub. Date: Jun. 23, 2016

(54) FLOATING GATE TRANSISTORS AND METHOD FOR FORMING THE SAME

(71) Applicant: WaferTech, LLC, Camas, WA (US)

(72) Inventors: Ke SUN, Portland, OR (US); Yimin WANG, Camas, WA (US)

(21) Appl. No.: 14/968,353

(22) Filed: Dec. 14, 2015

Related U.S. Application Data
(60) Provisional application No. 62/095,665, filed on Dec. 22, 2014.

(51) Int. Cl. H01L 29/788; H01L 27/115; H01L 21/762; H01L 29/161; H01L 21/28; H01L 29/06

(52) U.S. Cl. CPC H01L 29/7883; H01L 21/28273; H01L 29/0653; H01L 21/76224; H01L 29/161; H01L 27/11521

(57) ABSTRACT

A method and structure for floating gate transistors provides floating gate transistors with floating gates having sharp, well-controlled edge profiles. The sharp, well-controlled edge profiles enhance electrical functionality and endurance and are formed by a process including a planarization process that produces polysilicon segments disposed directly between adjacent STI structures, then forming a second polysilicon layer and patterning to form an upper polysilicon segment over the lower polysilicon segment to produce a combined polysilicon segment with a T-shape and having edges that overhang the adjacent edges of associated STI structures.

### RELATED APPLICATION

This application is a regular application based on and claiming priority of U.S. provisional application Ser. No. 62/095,665, entitled “Floating Gate Transistors and Method for Forming the Same,” filed Dec. 22, 2014, the contents of which are hereby incorporated by reference as if set forth in their entirety.

### BACKGROUND

A flash memory semiconductor device is a non-volatile storage device that can be electrically erased and reprogrammed. Flash memories are commonly used in memory cards, USB flash drives, and solid state drives for general storage and transfer of data between computers and other digital products. Flash memories typically store information in an array of memory cells made using floating gate transistors.

A floating gate transistor is a field effect transistor having a structure similar to a MOSFET (metal oxide semiconductor field effect transistor). Floating gate MOSFETs are distinguished from other MOSFETs because the floating gate transistor includes two gates instead of one. In addition to an upper control gate, a floating gate transistor includes an additional floating gate between the control gate and above the transistor channel, but completely electrically isolated by an insulating layer such as an oxide that completely surrounds the floating gate. This electrically isolated floating gate creates a floating node in DC (direct current) with a number of inputs for secondary gates such as the control gate, formed above the floating gate and electrically isolated from it. Because the floating gate is completely surrounded by highly resistive material, i.e. an insulating layer, any charge placed on the floating gate is trapped there and the floating gate remains unchanged for long periods of time until the floating gate MOSFET is erased. These devices, however, are regularly be erased.

To erase such a flash cell, a large voltage of the opposite polarity is applied between the control gate and the source, causing electrons to exit the floating gate through quantum tunneling. In this manner, the electrical charge is removed from the floating gate. It is therefore desirable to produce floating gate transistors which are easily erased, i.e. floating gate transistors in which the electrical charge is easily removed from the floating gate.

### BRIEF DESCRIPTION OF THE DRAWING

Embodiments of the present disclosure are best understood from the following detailed description when read in conjunction with the accompanying drawing.

It is emphasized that, according to common practice, the various features of the drawing are not necessarily to scale. On the contrary, the dimensions of the various features are arbitrarily expanded or reduced for clarity. Like numerals denote like features throughout the specification and drawing.

Each of the sets of figures includes an “A” figure illustrating a plan view, for example FIG. 1A, and “B” and “C” designated figures showing cross-sectional views, for example FIGS. 1B and 1C. The cross-sectional views of the “B” and “C” figures, are taken along the location indicated in the plan view figure.

FIGS. 1A-1C, 2A-2C, 3A-3C, 4A-4C, 5A-5C, and 6A-6C are each a set of figures described above and together, FIGS. 1A-1C, 2A-2C, 3A-3C, 4A-4C, 5A-5C, and 6A-6C show a sequence of processing operations used to form split gate transistors according to some embodiments of the disclosure.

### DETAILED DESCRIPTION

Embodiments of the disclosure provide a method for forming a flash memory device. More particularly, various embodiments of the disclosure provide for forming split gate transistors which are formed in an array according to some embodiments. The method avoids the use of LOCOS (Local Oxidation of Silicon), which is a thermal oxidation process that is inherently difficult to control and which produces unreliable tips of the floating gate structures and has been known to cause loss and breakage of the underlying floating gates. The poor tip profile includes tips that are rounded and this causes failures in endurance of the device and in erase operations because sharp tips are required for a concentrated electric field to perform the erase operations. The method provided by the present disclosure avoids the use of LOCOS, as above, and uses a re-deposition of a polysilicon or other semiconductor film to form transistor floating gates with superior and reliably controlled tips. The floating gate has a well-controlled, sharp tip profile for superior electrical functionality. The sharp tip profile enables the floating gate transistor to be easily erased as it allows for high electric field and enables Fowler-Nordheim tunneling thereby avoiding errors in the erase operations. The superior electrical functionality provided by the sharp tip profile enables better control of floating gate-to-control gate capacitance and tunneling distance, and more degrees of freedom for the coupling ratio tuning and scaling.

The method used in embodiments of the disclosure provides for a process flow with a reduced amount of furnace processing operations. In various embodiments the process flow avoids the use of LOCOS and other furnace formed films, which reduces manufacturing time and cost.

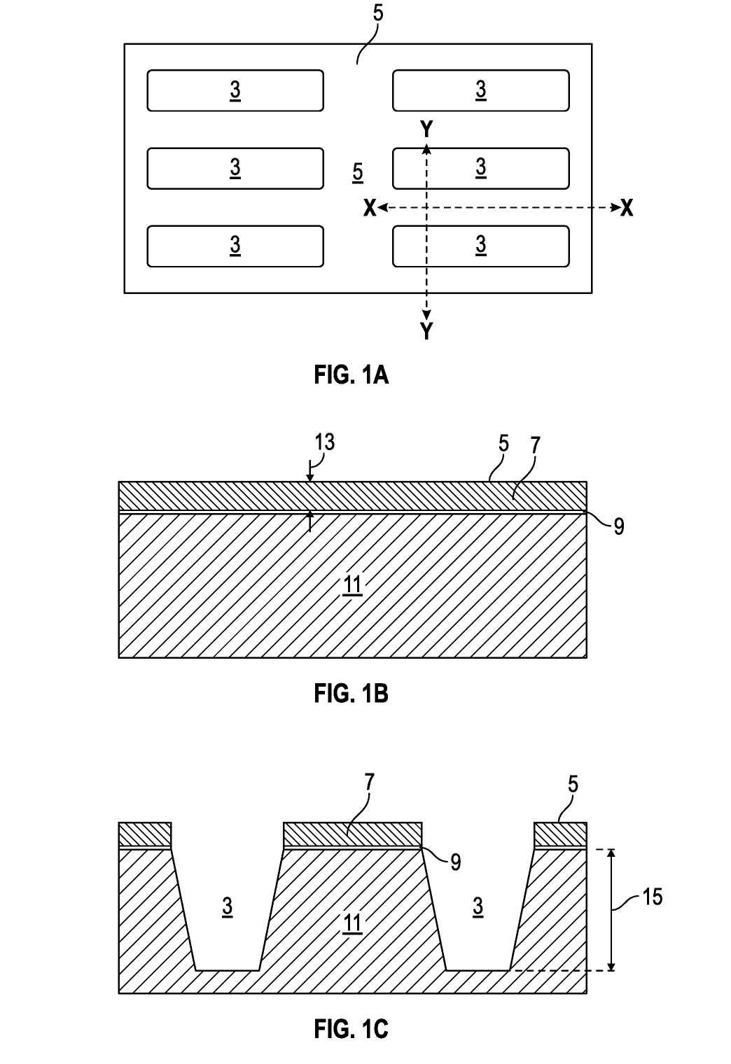

FIG. 1A provides a top view and FIGS. 1B and 1C represent cross-sectional views taken along the X-X and Y-Y lines, respectively identified in FIG. 1A. This format is true for each set of FIGS. 1A-1C trough 6A-6C.

FIGS. 1A-1C illustrate an initial step in the sequence of processing operations used to form split gate floating gate transistors according to various embodiments of the disclosure. FIGS. 1A-1C illustrate a plurality of trenches 3 extending downwardly from a surface 5 of a first semiconductor layer 7 formed over a floating gate dielectric 9 formed over substrate 11. Substrate 11 is a silicon substrate in some embodiments, but in other embodiments, substrate 11 is formed of other suitable semiconductor materials such as SiGe or other non-semiconductor materials used as substrates in the fabrication of semiconductor devices. In some embodiments, substrate 11 represents one or more film layers disposed over a bulk substrate such as a silicon wafer. Floating gate dielectric 9 is an oxide in some embodiments and floating gate dielectric 9 is another suitable floating gate dielectric in other embodiments. Floating gate dielectric 9 includes a thickness determined by the operating characteristics of the floating gate transistor. In some embodiments, the thickness of floating gate dielectric 9 may range from about 70-110 angstroms, but other thicknesses are used in other embodiments and the thickness is chosen in conjunction with other device features and dimensions and determined by various operational factors.

First semiconductor layer 7 is formed of polysilicon in some embodiments, and the polysilicon may be doped or undoped. In other embodiments, first semiconductor layer 7 may be formed of silicon germanium, amorphous silicon or other suitable semiconductor materials. First semiconductor layer 7 includes a thickness 13 that may be about 1000 angstroms in some embodiments, and may range from about 500-1500 angstroms in other embodiments, although other thicknesses are used in other embodiments and the thickness may eventually be receded as will be shown later. First semiconductor layer 7 is formed using various deposition processes such as chemical vapor deposition, CVD, or other suitable film formation processes. Trenches 3 extend downwardly from surface 5 of first semiconductor layer 7, through first semiconductor layer 7 and through floating gate dielectric 9 and into substrate 11. Trenches 3 extend into substrate 11 by a depth 15 that may range from about 2000 A to about 6000 A in various embodiments. Trenches 3 may be formed by a patterning operation followed by an etching operation that etches through first semiconductor layer 7, floating gate dielectric 9 and into substrate 11 to form trenches 3 shown in cross-section in FIG. 1C in which the unetched portions of first semiconductor layer 7, floating gate dielectric 9 and substrate 11 are aligned with one another. Various patterning and etching operations may be used.

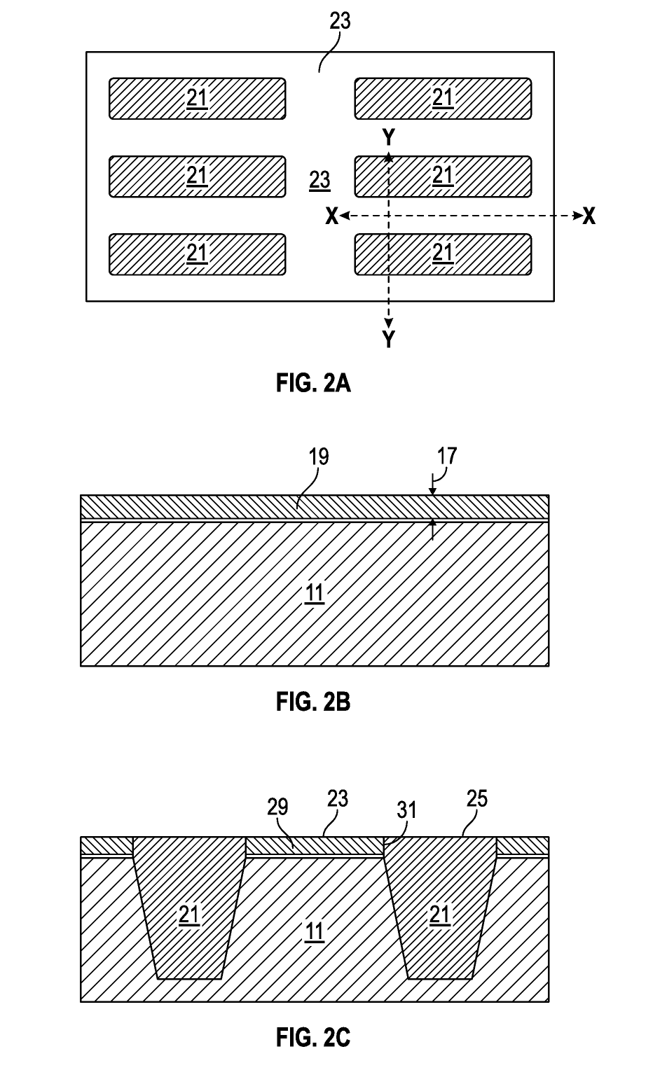

FIGS. 2A-2C show the structure shown in FIGS. 1A-1C after further processing. First, a dielectric deposition operation is carried out to fill trenches 3 of FIGS. 1A-1C. In some embodiments, a high density plasma (HDP) oxide deposition operation is used to fill trenches 3 to form STI (shallow trench isolation) structures. In other embodiments, other dielectric deposition methods are used. In addition to filling trenches 3, the dielectric deposition operation also forms the deposited dielectric over surface 5 in some embodiments. A polishing operation is then carried out to remove excess dielectric and to expose first semiconductor layer 7, such as shown in FIGS. 2A-2C. In some embodiments, the polishing is a planarization operation such as chemical mechanical polishing, CMP, but other polishing operations are used in other embodiments. In some embodiments, the CMP operation uses the first semiconductor layer 7 as a stopping material and terminates when surfaces 5 (see FIGS. 1B, 1C) are exposed. In other embodiments, the polishing operation continues and recedes first semiconductor layer 7 to various degrees. In some embodiments in which first semiconductor layer 7 is not receded, thickness 17 of polished first semiconductor layer 19 is the same as thickness 13 shown in FIG. 1B. According to embodiments in which the surface is receded, thickness 17 may be less than thickness 13 by about 50-750 angstroms in some embodiments. According to either embodiment, the polishing operation produces STI structures 21 extending downwardly from polished surface 23. STI structures 21 include top surface 25 that is coplanar with polished surface 23 of polished first semiconductor layer 19. As seen most clearly in FIG. 2C, polished first semiconductor layer 19 includes segment 29 (the central portion of polished first semiconductor layer 19) disposed between and bordering adjacent STI structures 21. Segment 29 includes edges 31 that form a conterminous boundary with the upper edges of STI structures 21. In some embodiments, edges 31 are straight and vertical.

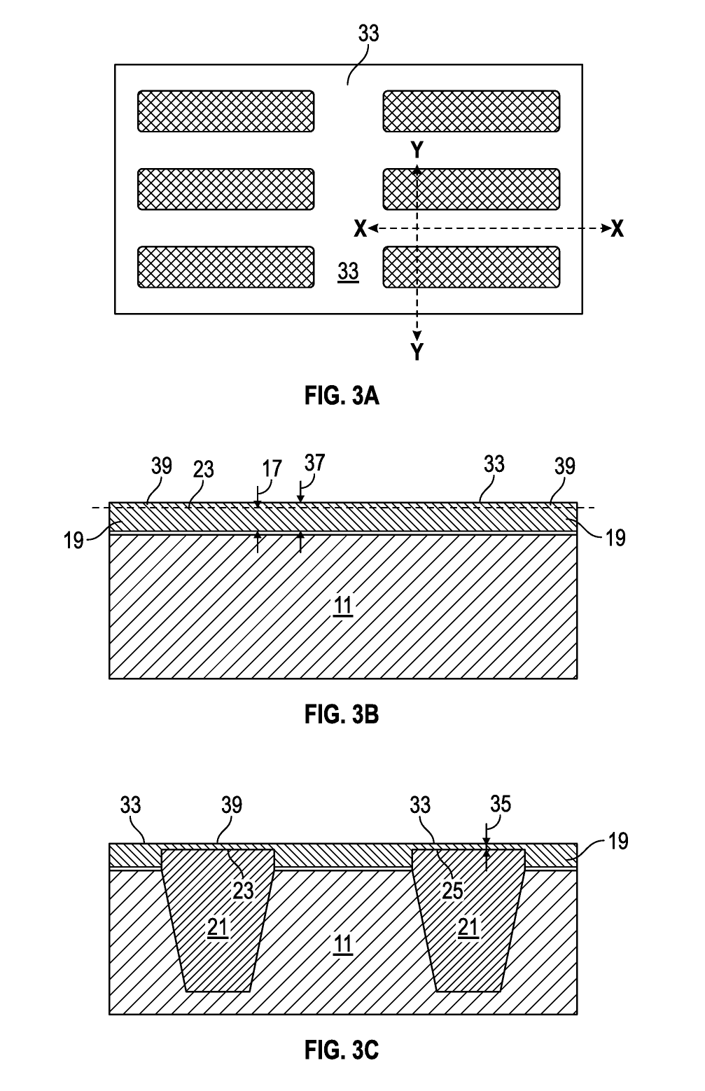

FIGS. 3A-3C show the structure of FIGS. 2A-2C after a further semiconductor layer has been formed. In FIGS. 3A-3C, further semiconductor layer 33 is disposed over the planar top surface that was shown in FIGS. 2B and 2C. In particular, further semiconductor layer 33 is formed over top surface 25 of STI structure 21 and over polished surface 23 of polished first semiconductor layer 19. In FIGS. 3A-3C, further semiconductor layer 33 is formed directly on top surface 25 of STI structure 21 and polished surface 23 of polished first semiconductor layer 19. The dashed line indicates polished surface 23 and the border between further semiconductor layer 33 and polished first semiconductor layer 19. In some embodiments, each of first semiconductor layer 7 and further semiconductor layer 33 are formed of polysilicon. In some embodiments, first semiconductor layer 7 and further semiconductor layer 33 are both formed of silicon germanium. Further semiconductor layer 33 includes a thickness 35 that may range from about 10-200 angstroms and may be about 100 angstroms in some embodiments, but different thicknesses are used in other embodiments. Thickness 35 is chosen in conjunction with thickness 17 of polished first semiconductor layer 19 to produce a floating gate of sufficient total thickness and to produce a floating gate tip of desired configuration. In some embodiments, the combined thickness 37 may be about 500 A to 1500 A in various embodiments. Further semiconductor layer 33 includes top surface 39.

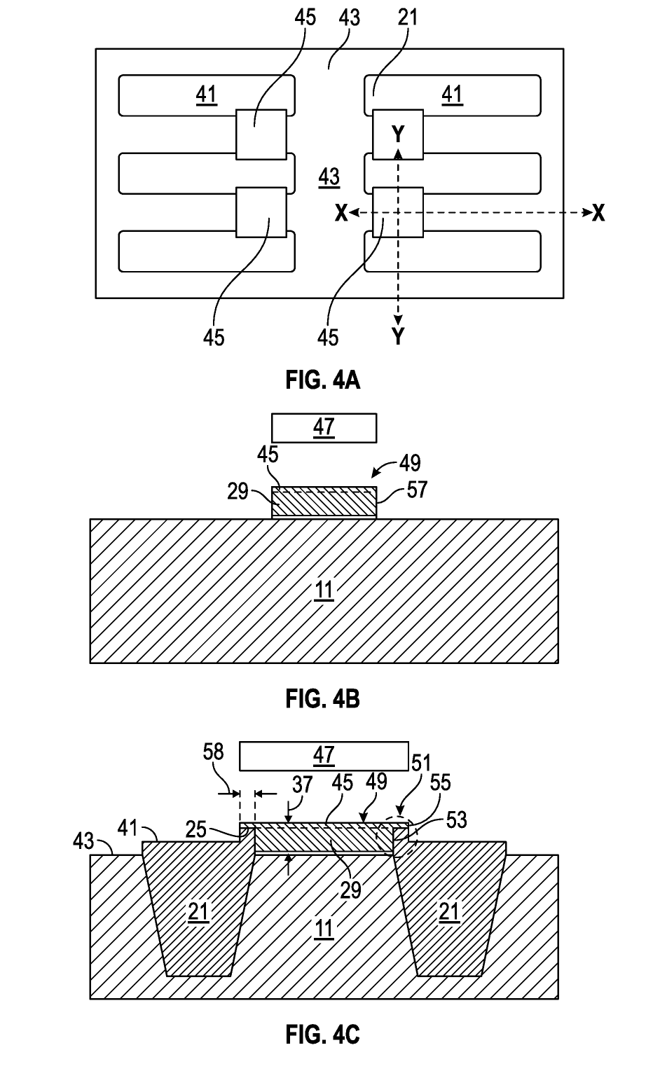

A patterning and etching operation sequence is then carried out to convert the structure shown in FIGS. 3A-3C to the structure shown in FIGS. 4A-4C. FIGS. 4A-4C show discrete portions 45 of further semiconductor layer 33 formed by a patterning and etching process sequence. Photomask portion 47 is shown schematically over discrete portion 45 in FIGS. 4B and 4C to represent the patterning operation. The etching operation selectively etches the material of further semiconductor layer 33 and in some embodiments also includes an overetch portion that recedes the previous top surface 25 of STI structures 21. The etching operation is a dry etching operation in various embodiments. In some embodiments, receded top surface 41 of STI structure 21 is produced and is receded with respect to original top surface 25 of STI structure 21. STI structures 21 include edges with top surface 25 that extend above upper surface 43 to a greater height than the receded top surface 41 of other portions of STI structure 21.

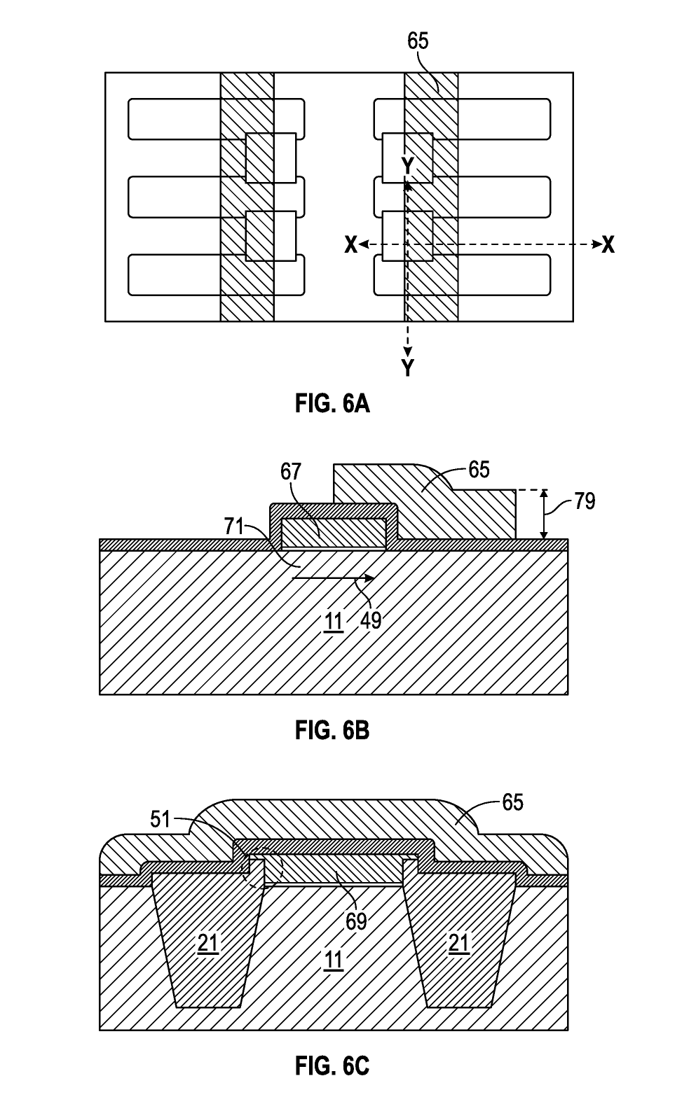

Discrete portions 45 of further semiconductor layer 33 overhang the associated adjacent STI structures 25. Discrete portions 45 of further semiconductor layer 33 combine with segment 29 of polished first semiconductor layer 19 to form T-shaped floating gate segment 49. Along one lateral direction such as shown in FIG. 4B, T-shaped floating gate segment 49 has opposed edges 57 that are essentially vertical in some embodiments. It will be seen (see FIGS. 6A-6C) that the cross-sectional view of FIG. 4B, which corresponds to the cross-sectional view of FIG. 6B, is taken along the channel direction of a floating gate transistor that will be subsequently formed.

In the lateral direction orthogonal to the view shown in FIG. 4B, i.e., the view shown in FIG. 4C, T-shaped floating gate segment 49 includes an opposed set of overhang edges 51. Overhang edges 51 include a lower section with a vertical sidewall 53 that forms a boundary with the associated adjacent STI structure 21. Overhang edges 51 also include overhang portions 55 that extend outwardly past vertical sidewall 53 and partially over STI structures 21. Overhang section 55 may extend about 10-100 nm past vertical sidewall 53 in some embodiments (distance 58), but other dimensions are used in other embodiments. Overhang edges 51 provide a sharp, superior floating gate tip that amplifies the electric field and facilitates Fowler-Nordheim tunneling and avoids the pitfalls associated with rounder edges as produced according to conventional embodiments.

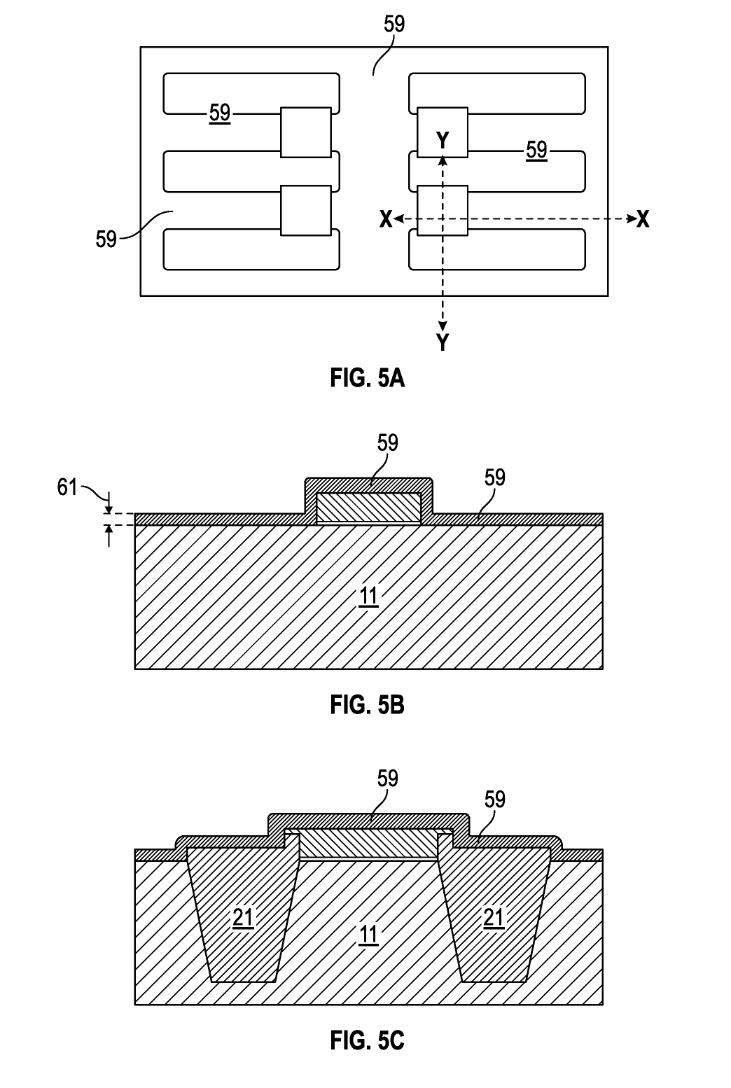

A dielectric is formed over the structures shown in FIGS. 4A-4C to produce the structure shown in FIGS. 5A-5C.

FIGS. 5A-5C show dielectric 59. In some embodiments, dielectric 59 is an inter-poly oxide, but other suitable dielectrics are used in other embodiments. Dielectric 59 includes thickness 61 that may range from about 100-300 angstroms in various embodiments and may be about 200 angstroms in some embodiments. Dielectric 59 will serve as the inter-gate dielectric for a floating gate transistor and thickness 61 is chosen in conjunction with the operational characteristic s of the floating gate transistor being formed. Various dielectric deposition processes are used to form dielectric 59.

FIGS. 6A-6C show the structure of FIGS. 5A-5C after a control gate has been formed. The control gate is formed by first depositing a layer of polysilicon or other suitable material such as germanium or metal gate material, over the structure shown in FIGS. 5A-5C, then patterning to form the structure shown in FIGS. 6A-6C. FIGS. 6B and 6C show that control gate is conformally disposed over the underlying structure. Control gate 65 extends partially over floating gate 67, as shown most clearly in FIG. 6B, which shows the structure along the channel direction 69. Control gate 65 extends partially over floating gate 67 which is disposed over channel 71 and thus forms a split gate transistor as shown most clearly in FIG. 6B. Channel direction 69 is the direction electrons flow from the source to the drain (not shown) through channel 71 when the split gate floating gate transistor is functioning. FIG. 6B shows most clearly that control gate 65 extends only partially but not completely over floating gate 67.

Control gate 65 is formed of polysilicon in some embodiments, but may be formed of other materials in other embodiments, and includes thickness 79 of about 1,500-2,500 angstroms, and thickness 79 may be about 2,000 angstroms in various embodiments, but other thicknesses are used in other embodiments. It can be seen that T-shaped floating gate segment 49 serves as the floating gate of the split gate floating gate transistor. In the direction orthogonal to the channel direction, i.e. the direction shown in FIG. 6C, the floating gate 67 includes overhang edges 51 that overhang the associated STI structure 21 and conformal control gate 65 conforms to the underlying structure formed of overhang edges 51 and dielectric 59, particularly in the region around overhang edges 51.

Overhang edges 51 provide a sharp tip that is well controlled and provides the aforementioned advantages.

It should be noted that the dimensions provided above are intended to serve as examples and are not limiting of the features and dimensions of the disclosure. Dimensions such as thicknesses are chosen in conjunction with the desired operational characteristics of the floating gate transistors and the dimensions of a particular feature are typically chosen in conjunction with the dimensions of associated features and design rules to provide high functioning floating gate transistor devices.

Although the cross-sectional views of the foregoing sequence of processing operations were shown with respect to a single transistor device to show additional detail and for clarity, it should be understood that the cross-sectional views represent only a portion of the plan view shown in the “A” figures. Although the processing sequence was described and illustrated in conjunction with a single transistor device, the processing sequence of the disclosure is used to simultaneously form a plurality of floating gate transistor devices in various arrays and other arrangements.

In some embodiments, a method for forming floating gate transistors is provided. The method comprises: forming trench openings in a substructure that includes a semiconductor layer over a floating gate oxide over a semiconductor substrate; filling the trench openings with a dielectric to form STI (shallow trench isolation) structures; planarizing to produce a coplanar upper surface that includes portions of upper surfaces of the STI structures and portions of a top surface of the semiconductor layer; depositing a further semiconductor layer over the coplanar upper surface; and patterning and etching the further semiconductor layer to produce discrete semiconductor portions of the further semiconductor layer, the discrete semiconductor portions having edges that overhang adjacent STI edges of the STI structures.

According to other aspects, an array of floating gate transistor is provided. Each floating gate transistor has a channel and a floating gate disposed over the channel, the floating gate having opposed lateral edges at opposed ends of the floating gate and, in a direction orthogonal to a channel direction. The floating gate includes opposed overhang edges, each including a vertical edge portion that forms a boundary with an associated adjacent STI (shallow trench isolation) structure and an overhang portion that extends outwardly past the vertical edge portion and overhangs the associated adjacent STI structure.

According to other aspects, a method for forming an array of floating gate transistors, is provided. The method comprises: forming trench openings in a substructure that includes a polysilicon layer over a floating gate dielectric over a substrate, the polysilicon layer having a first thickness; filling the trench openings with a dielectric to form STI (shallow trench isolation) structures; polishing to produce a coplanar upper surface that includes portions of upper surfaces of the STI structures and a receded top surface of the polysilicon layer, the polished polysilicon layer having a thickness less than the first thickness; and depositing a further polysilicon layer over the coplanar upper surface. The method also comprises patterning and etching the further polysilicon layer to produce polysilicon segments formed of the first and further polysilicon layers, the polysilicon segments having edges with portions that overhang adjacent STI edges of the STI structures; and forming a split-gate floating gate transistor using the polysilicon segments as associated floating gates.

The preceding merely illustrates the principles of the disclosure. It will thus be appreciated that those skilled in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended examples should be construed broadly, to include other variants and embodiments of the disclosure, which may be made by those skilled in the art without departing from the scope and range of equivalents of the disclosure.

1. A method for forming floating gate transistors, said method comprising:
providing a semiconductor structure with a coplanar upper surface that includes portions of upper surfaces of shallow trench isolation (STI) structures and portions of a top surface of a semiconductor layer;
depositing a further semiconductor layer over said coplanar upper surface; and
patterning and etching said further semiconductor layer to produce discrete semiconductor portions of said further semiconductor layer, said discrete semiconductor portions having edges that overhang adjacent STI edges of said STI structures.

2. The method as in claim 1, wherein each of said semiconductor layer and said further semiconductor layer comprises polysilicon.

3. The method as in claim 1, wherein said providing includes forming trench openings in a substructure that includes said semiconductor layer and filling said trench openings with a dielectric using a high density plasma (HDP) process to form said STI structures, and wherein said semiconductor layer is disposed over a floating gate oxide disposed over a semiconductor substrate.

4. The method as in claim 3, wherein said forming trench openings includes etching said substructure to produce said trench openings extending downwardly from said top surface of said semiconductor layer, through said semiconductor layer and said floating gate oxide and into said semiconductor substrate and wherein portions of said semiconductor layer include semiconductor segments that extend between and abut said STI structures.

5. The method as in claim 3, further comprising planarizing after said filling said trench openings with a dielectric, using a chemical mechanical polishing (CMP) operation that terminates when said semiconductor layer is exposed.

6. The method as in claim 1, wherein each of said semiconductor layer and said further semiconductor layer comprise polysilicon and said coplanar upper surface includes polysilicon segments of said semiconductor layer disposed between said STI structures, and
wherein said patterning and etching produce polysilicon structures including said discrete semiconductor portions over said polysilicon segments such that said polysilicon structures include lower portions that extend between and abut said STI structures and upper portions that include said edges that overhang said adjacent STI edges of said STI structures.

7. The method as in claim 6, further comprising, after said patterning and etching, depositing an IPO (inter-poly oxide) over said polysilicon structures, then forming control gates over said IPO and extending partially but not completely over said polysilicon structures.

8. The method as in claim 6, wherein said polysilicon structures further include a set of opposed second edges that bound said polysilicon segments in a direction orthogonal to said edges, and wherein said second edges are substantially vertical.

9. The method as in claim 1, wherein said edges each overhang an adjacent STI structure of said STI structures by a distance ranging from about 10-100 nm and each include a thickness ranging from about 10 angstroms to about 200 angstroms.

10. The method as in claim 1, further comprising, after said patterning and etching, forming a floating gate oxide over said polysilicon structures without using local oxidation of silicon (LOCOS) thermal processing.

11. The method as in claim 1, wherein each of said semiconductor layer and said further semiconductor layer comprise silicon germanium, and further comprising, after said patterning and etching, depositing a dielectric over said polysilicon structures, then conformally forming control gates over said dielectric.

12. An array of floating gate transistors, each said floating gate transistor having a channel and a floating gate disposed over said channel, said floating gate having opposed lateral edges at opposed ends of said floating gate and, in a direction orthogonal to a channel direction, said floating gate including opposed overhang edges, each including a vertical edge portion that forms a boundary with an associated adjacent shallow trench isolation (STI) structure and an overhang portion that extends outwardly past said vertical edge portion and overhangs said associated adjacent STI structure.

13. The array of floating gate transistors as in claim 12, wherein said overhang portion overhangs an edge of said STI structure by a distance ranging from about 400-100 nm.

14. The array of floating gate transistors as in claim 12, wherein said adjacent STI structures include edge portions beneath said overhang portions, and further portions, wherein said edge portions extend above a surface of a semiconductor substrate within which said STI is formed, to a greater extent than said further portions.

15. The array of floating gate transistors as in claim 12, wherein said opposed lateral edges are opposed edges of a side that extends along the same direction as a channel direction.

16. The array of floating gate transistors as in claim 12, wherein each said floating gate is formed of polysilicon and said overhang portions include a thickness ranging from about 10 angstroms to about 200 angstroms.

17. The array of floating gate transistors as in claim 12, wherein each said floating gate transistor includes an associated control gate that extends partially but not completely over said floating gate along a channel direction.

18. The array of floating gate transistors as in claim 12, wherein said associated adjacent STI structure includes an edge portion beneath said overhang portion and which extends above a surface of a semiconductor substrate within which said STI is formed.

19. A method for forming an array of floating gate transistors, said method comprising:
forming trench openings in a substructure that includes a polysilicon layer over a floating gate dielectric over a substrate, said polysilicon layer having a first thickness;
filling said trench openings with a dielectric to form STI (shallow trench isolation) structures;
polishing to produce a coplanar upper surface that includes portions of upper surfaces of said STI structures and a receded top surface of said polysilicon layer, said polished polysilicon layer having a thickness less than said first thickness;
depositing a further polysilicon layer over said coplanar upper surface;
patterning and etching said further polysilicon layer to produce polysilicon segments formed of said first and further polysilicon layers, said polysilicon segments having edges with portions that overhang adjacent STI edges of said STI structures; and
forming a split-gate floating gate transistor using said polysilicon segments as associated floating gates.

20. The method as in claim 19, wherein said STI structures include said STI edges and further portions, wherein said STI edges extend above a surface of said semiconductor substrate to a greater height than said further portions.
